(19) United States
(12) Patent Application Publication
(10) Pub. No.: US 2025/0160037 A1
(43) Pub. Date: May 15, 2025

(54) Method for manufacturing a diode radiation sensor

(71) Applicant: Fondazione Bruno Kessler, Povo (TN) (IT)

(72) Inventors: Giacomo Borghi, Trento (TN) (IT); Giovanni Paternoster, Trento (IT); Maurizio Boscardin, Rovereto (IT); Nicolò Cartiglia, Milano (IT); Valentina Sola, La Loggia (IT)

(21) Appl. No.: 18/839,431

(22) PCT Filed: Feb. 22, 2023
(86) PCT No.: PCT/IB2023/051599

§ 371 Date: Aug. 18, 2024

(30) Foreign Application Priority Data
Feb. 23, 2022 (IT) 102022000003359

(51) Int. Cl. H10F 71/00; H10F 30/00

(52) U.S. Cl. CPC H10F 71/134; H10F 30/301; H10F 71/121

(57) ABSTRACT

A manufacturing method of a diode radiation sensor having a charge multiplication diode includes providing a substrate that is made of a semiconductor material and has a front surface and a rear surface; making, near the front surface, a first layer of a semiconductor material having a first type of doping; and making, deep in the substrate, a second layer of a semiconductor material having a second type of doping that is electrically opposite to the first type. The second layer is obtained by inserting into the substrate a first predetermined amount of a first type of dopant and a second predetermined amount of a second type of dopant.

### FIELD OF APPLICATION

The present invention can be applied to the field of diode sensors and, in particular, to the field of radiation sensors.

More in detail, the present invention finds particular but not exclusive application to the field of diode radiation sensors having one or more diodes with charge multiplication structure powered so as to work in linear multiplication regime.

### BACKGROUND ART

Radiation sensors are used in a wide variety of applications, ranging from industrial to scientific. In many cases, the detector is constructed on a single body of semiconductor material, for example silicon, divided into several microcells or channels (also called pixels and/or microstrips), each typically consisting of an individually accessible diode.

A typical example of an ionizing radiation detector consists of a silicon microstrip with a typical thickness of a few hundred μm. Such a device is used for detecting ionizing radiation (such as charged particles or X-rays) in scientific experiments and for industrial applications.

The active area of the detector is divided into several parallel strips, with a width usually between 25 μm and a few hundred micrometres.

As a first approximation, the above sensors do not have an internal gain and thus have a limit if the amount of charge created by the ionizing radiation is too low to be measured accurately.

To improve performance, it was thus decided to introduce a charge multiplication structure inside the diode which allows them to operate, when appropriately polarized, in linear charge multiplication regime, which means that the charge collected at the output of each channel is proportional to the charge generated by the radiation which interacts with the sensor.

In some cases, such as in the case of measuring the interaction time of charged particles at the minimum ionization in high-energy physics experiments, the charge amplification provided by the diode must be sufficient to allow the detection of the radiation and to obtain an optimal working point considering the ratio between the signal and the noise, but not excessive to avoid impairing the accuracy of the measurement due to the worsening of the signal/noise ratio due to the excess noise determined by the charge multiplication process. For this reason, the diodes used are usually powered so that the gain is particularly limited and with values in the range of 10 to 30. In such a case LGADs are spoken of, i.e., Low-Gain Avalanche Diodes.

Given the type of function which LGADs have and the type of radiation they must measure, the sensors implementing them have active thicknesses which typically range from a few tens to a few hundreds of μm.

One of the most important problems that the aforementioned sensors must face is the fact that their exposure to even intense radiation causes a gradual deterioration thereof.

As is known, in fact, the diode multiplication structures at the base of such sensors are made by appropriately doping a substrate made with a semiconductor (typically, but not exclusively, silicon). The aforesaid radiation can interact with the thus-doped substrate causing the deactivation of the dopant, that is, the removal of the dopant from the crystal lattice, and the return to the original position of semiconductor atoms that the dopant had replaced. In other words, exposure to radiation causes a reduction in the concentration of active dopant in the diodes forming the sensor, decreasing the gain of the junction area of such diodes. This results in a loss of sensor detection accuracy.

In particular, a first drawback is constituted by the fact that the gain of the sensor decreases over time.

A further disadvantage, related in particular to LGAD applications, is constituted by the fact that, since the diode is powered so as to have a limited gain (typically between 10 and 30), the decrease in the doping causes, at the same power supply voltage of the diode, a decrease in the gain.

### Presentation of the Invention

The object of the present invention is to at least partially overcome the drawbacks noted above, providing an execution method of a diode radiation sensor which allows such sensors to better resist the deteriorating effects of the radiation to which they are exposed.

In particular, an object of the present invention is to provide an execution method of a diode sensor which allows to limit, if not cancel, the deactivation effect of dopant particles in the diodes forming the sensor.

Another object of the present invention is to provide an execution method of a diode sensor having low costs and as comparable as possible to the costs of the known equivalent methods.

It follows that a further object of the present invention is to provide an execution method of a diode sensor which introduces the least possible modifications to the known execution methods currently used for the execution of such sensors.

It is obvious, from what has been said, that another object of the present invention is to provide a diode radiation sensor which is more resistant to the radiation to which it must be subjected in order to limit, if not cancel, the decay of the gain of the diodes forming it.

Such objects, as well as others which will become clearer below, are achieved by an execution method of a diode radiation sensor in accordance with the following claims, which are to be considered as an integral part of the present disclosure.

In particular, the method of the invention allows to make a diode radiation sensor of the type comprising at least one charge multiplication diode.

Firstly, the method comprises a step of preparing a substrate made of semiconductor material. Such a substrate has a front surface and a rear surface opposite the front surface.

At least a first layer of semiconductor material doped with a first predetermined amount of a first type of dopant is then made near the front surface of the substrate.

Subsequently, at least a second layer of semiconductor material doped with a second predetermined amount of a second type of dopant electrically opposite the first type of dopant is then made deep in the substrate.

Obviously, the sequence of doping operations can be any without any limit for the present invention, the formation of the two layers can be reversed. Furthermore, for the creation of electronic components of various types, numerous other steps can be envisaged both before and during the two aforementioned steps as well as interposed therebetween without any limit for the present invention.

In any case, according to an aspect of the invention, the second layer is obtained by inserting (with implantation or surface diffusion technique), in a same zone of the substrate where the second layer is to be located, a first predetermined amount of a first type of dopant and a second predetermined amount of a second type of dopant. In particular, the second predetermined amount of dopant characteristic of the second layer is obtained by differential between the effects of insertion of the first predetermined amount of the first dopant and the second predetermined amount of the second dopant.

Also in this case, the order of execution of the two insertion steps can be any, what is important being the final result, i.e., that the second amount of the second type of dopant in the second layer is reached. Moreover, according to some embodiments of the invention, the two insertion steps are contextual.

It should be noted that the technique used is that of compensation, i.e., to obtain the aforesaid second amount of dopant, two dopants of the opposite sign are inserted into the substrate in the same area with one that compensates for the second.

In the case of the present invention, typically the layers of doped semiconductor material are obtained by inserting a single type of dopant and not two competing types, resorting to the compensation of one with respect to the other. In the present case, such a technique allows to obtain some fundamental advantages.

Firstly, it is possible to increase the presence density of the second dopant while maintaining the second predetermined amount of dopant of the second layer by virtue of the above-mentioned compensation. This increased density makes it possible to mitigate the harmful effects of the radiation striking the sensor of the invention when in use, since with high densities of the second dopant the above-mentioned and radiation-stimulated recombination is hindered.

Still advantageously, the second predetermined amount of the second dopant can be increased at will, thereby allowing to make radiation sensors whose resistance to the harmful effects of the radiation is optimized.

Still advantageously, if even the radiation were able to deactivate even small portions of the second predetermined amount of second dopant, the same effect is induced on the first predetermined amount of first dopant, thereby leaving the gain of the diode substantially unchanged in accordance with its operating polarization.

Advantageously, therefore, the execution of the second layer with the compensation technique allows to reduce, if not cancel, the degradation of the sensor when subjected to radiation.

Since such a result is obtained with the simple addition of an insertion operation with respect to the known equivalent methods (the implantation or the diffusion of compensation) it is evident that the execution cost of the radiation sensor of the invention is substantially comparable to the execution cost of the equivalent sensors of the prior art.

Moreover, the modification introduced to the normal execution methods of the known sensors can be easily executed without therefore weighing on the executive complexity of the radiation sensor.

According to the above, it is evident that said objects are also achieved by a diode radiation sensor made with the method just described.

### BRIEF DESCRIPTION OF THE DRAWINGS

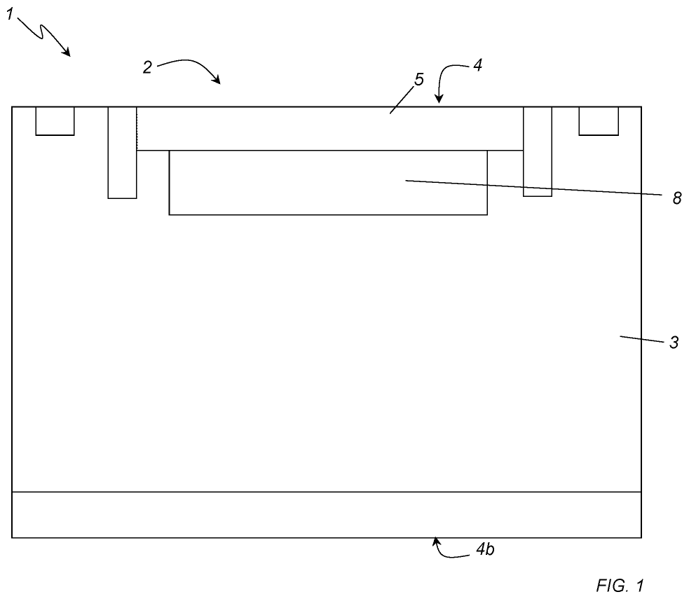

Further features and advantages of the invention will become more evident in light of the detailed description of a preferred but non-exclusive embodiment of a radiation sensor according to the invention, illustrated by way of non-limiting example with the aid of the accompanying drawings, in which FIG. 1 depicts a radiation sensor made according to the method of the invention.

### DETAILED DESCRIPTION OF AN EXEMPLARY PREFERRED EMBODIMENT

With reference to the above mentioned FIGURE, an execution method of a diode radiation sensor 1 having one or more charge multiplication diodes 2 is described. According to the embodiment which is described, such charge multiplication diodes 2 are intended to be polarized so as to work in a linear multiplication zone, being LGAD, but such an aspect must not be considered limiting for the invention.

For ease of description, the sensor 1 depicted in the FIGURE comprises a single diode 2, but it is evident that such an aspect must also not be considered limiting for the present invention.

The method of the invention firstly includes a step of preparing a substrate 3 made of semiconductor material and having two surfaces, a front surface 4 and a rear surface 4b opposite the front surface 4. Such a substrate 3, given the use of the embodiment described in the context of the aforementioned LGAD, has a typically high depth and of the order of a few hundred μm or, typically but not necessarily, of at least 20 μm. It is also typically slightly doped, but such an aspect is also not limiting for the present invention.

Always according to the embodiment which is described, the substrate 3 is made of silicon, but also such an aspect must not be considered limiting for the invention.

According to an aspect of the invention, there is then a step of making, near the front surface 4 of the substrate 3, a first layer 5 of semiconductor material doped with a first predetermined amount of a first type of dopant.

In the embodiment described, the doping of the first type is an N-type doping obtained by implanting phosphorus in the substrate 3, but this should not be considered limiting for different embodiments of the invention where the doping is different and/or the first type of dopant is a P-type dopant (in which case boron is typically, but not necessarily, used). Also the implantation technique used must not be considered as limiting for different embodiments of the invention where it is carried out by diffusion from the front surface.

Also the position of the first layer 5 near the front surface 4 of the substrate 3 is a feature which should not be considered limiting for the present invention, depth in the substrate, size and number of first layers being able to be any in accordance with the design needs of the radiation sensor.

According to another aspect of the invention, there is also a step of making, deep in the substrate 3, a second layer 8 of semiconductor material doped with a second predetermined amount of a second type of dopant electrically opposite the first type of dopant.

In accordance with what has been said above for the first layer 5, in the embodiment which is described, the second type of dopant is a P-type dopant typically executed by implanting boron in the substrate 3, but also in this case this should not be considered limiting for the present invention with regard to the specific dopant, and for the electrical sign, and for the technique used.

Also the position, size and number of second layers are non-limiting features for the present invention.

As previously mentioned, for the purposes of the present invention the sequence of doping operations can be any, the formation of the two layers can be reversed. Furthermore, for the creation of electronic components of various types, numerous other steps can be envisaged both before and during the two aforementioned steps as well as interposed therebetween without any limit for the present invention.

In any case, according to another aspect of the invention, the second layer 8 is obtained by inserting (whether by implantation or by diffusion from the front surface 4), in a same zone of the substrate 3 where the second layer 8 is to be located, a first predetermined amount of a first type of dopant and a second predetermined amount of a second type of dopant. In particular, the second predetermined amount of dopant characteristic of the second layer 8 is obtained by differential between the effects of insertion of the first predetermined amount of the first dopant and the second predetermined amount of the second dopant.

Even in this case, the order of execution of the two insertion steps can be any. In fact, the relevant aspect of the invention is that the second amount of the second type of dopant reaches the second layer 8.

In particular, the technique used is that of compensation, i.e., to obtain the aforesaid second predetermined amount of doping, two dopants of opposite sign with mutual compensation are inserted in the substrate 3, in the zone where the second layer 8 is to be arranged by design, so that the resultant corresponds to the second predetermined amount of dopant.

In the known equivalent radiation sensors the layers of doped semiconductor material are obtained by implanting a single type of dopant and not two competing types, resorting to the compensation of one with respect to the other. In the present case, such a compensation technique allows to obtain some fundamental advantages.

Firstly, it is possible to increase the presence density of the second dopant while maintaining the second predetermined amount of dopant of the second layer 8 by virtue of the above-mentioned compensation. This increased density makes it possible to mitigate the harmful effects of the radiation striking the sensor 1 of the invention since with high densities of dopant the above-mentioned and radiation-stimulated recombination is hindered.

Still advantageously, the first predetermined amount of the first dopant and the second predetermined amount of the second dopant can be increased at will in a coordinated manner, thereby allowing to make radiation sensors 1 whose resistance to harmful effects of radiation is optimized.

Moreover, advantageously, if even the radiation were able to deactivate even small portions of the second predetermined amount of second dopant, the same effect is induced on the first predetermined amount of first dopant, thereby leaving the gain of the diode 2 substantially unchanged in accordance with its operating polarization.

From what has been said, therefore, the execution of the second layer 8 with the compensation technique advantageously allows to reduce, if not cancel, the degradation of the sensor when subjected to radiation.

Since such a result is obtained with the simple addition of an insertion operation with respect to the known equivalent methods, it is evident that the execution cost of the radiation sensor 1 of the invention is substantially comparable to the execution cost of the equivalent sensors of the prior art.

Moreover, the modification introduced to the normal execution methods of the known sensors can be easily executed without therefore weighing on the executive complexity of the radiation sensor 1 of the invention.

With regard to the second predetermined amount of dopant of the second layer 8, its predetermined determination is carried out by means of design parameters of the sensor 1.

In particular, it is calculated on the basis of some features of the radiation sensor 1:
the thickness of the active volume of the detector, defined by the high-resistivity substrate part;
the profile of the junction doping, i.e., of the doping of the zone interposed between the front surface 4 of the sensor 1 and the second layer 8 (zone where the first layer 5 is arranged);
the doping profile of the second layer 8 (in the case of doping obtained by implantation, the profile is influenced by the implantation energy and the activation times thereof as well as by the subsequent thermal loads, in the case of diffusion from the surface, the profile is influenced by the diffusion times and technique, the activation temperature and the subsequent thermal loads);
the thermal load during the process;
the resistivity of the substrate 3;
the possible co-implantation of other non-electrically active elements;
the constraints on the electrical voltage to be applied to the radiation sensor 1 during the operational step;
the profile of the compensation doping.

From what has been said above, it is evident that the object of the present patent is also a radiation sensor 1 obtained with the method described above.

In such a sense, it comprises the charge multiplication diode 2 where the following are identified:
the substrate 3 made of semiconductor material;
the first layer 5 of semiconductor material doped with a first type of dopant;
the second layer 8 of semiconductor material doped with a resultant second type of dopant.

In light of the foregoing, it is understood that the execution method of a radiation sensor of the invention achieves all the preset objects.

In particular, it allows to make a diode radiation sensor particularly resistant to the deteriorating effects of the radiation to which they are subjected.

In fact, with the method of the invention, a radiation sensor has been made in which the effect of deactivating dopant particles in the diodes forming the sensor is limited, if not cancelled.

On closer inspection, the execution method of the invention has low costs and comparable to the costs of the known equivalent methods since it presents a small but significant variation in the execution process of the sensor consisting of the execution of the second layer with the compensation technique.

The invention is susceptible to numerous modifications and variations, all falling within the appended claims. Moreover, all the details may furthermore be replaced by other technically equivalent elements, and the materials may be different depending on needs, without departing from the protection scope of the invention defined by the appended claims.

The invention claimed is:

1. An execution method of a diode radiation sensor having at least one charge multiplication diode, said method comprising the following steps:
arranging a substrate made of a semiconductor material, said substrate having a front surface and a rear surface opposite said front surface;
making, at least near adjacently to said front surface of said substrate, at least a first layer of the semiconductor material having a first type of doping; and
making, in an interior of said substrate, a second layer of the semiconductor material having a second type of doping that is electrically opposite to said first type of doping,
wherein said second layer is obtained by inserting, in a zone of said substrate where said second layer is to be located, a first predetermined amount of a first dopant of said first type and a second predetermined amount of a second dopant of said second type, and
wherein said second type of doping is obtained by differential between effects of said inserting said first predetermined amount of said first dopant and said second predetermined amount of said second dopant so as to be able to increase at will said second predetermined amount of said second dopant, thereby mitigating effects, at least on said second type of doping, of radiation striking said second layer.

2. The execution method according to claim 1, wherein said first dopant is an n-type dopant, said second dopant being a p-type dopant.

3. The execution method according to claim 2, wherein said first dopant is phosphorus and said second dopant is boron.

4. The execution method according to claim 1, wherein said first dopant is a p-type dopant, said second dopant being an n-type dopant.

5. The execution method according to claim 4, wherein said first dopant is boron and said second dopant is phosphorus.

6. The execution method according to claim 1, wherein said semiconductor material is silicon.

7. The execution method according to claim 1, wherein said inserting said first predetermined amount of said first dopant and said second predetermined amount of said second dopant occurs with an implantation technique.

8. The execution method according to claim 1, wherein said inserting said first predetermined amount of said first dopant and of said second predetermined amount of said second dopant occurs with a diffusion technique from the front surface.
